(19) United States
(12) Patent Application Publication
(10) Pub. No.: US 2024/0017376 A1
(43) Pub. Date: Jan. 18, 2024

(54) MONITORING THICKNESS IN FACE-UP POLISHING WITH ROLLER

(71) Applicant: Applied Materials, Inc., Santa Clara, CA (US)

(72) Inventors: Brian J. Brown, Palo Alto, CA (US); Chirantha Rodrigo, Santa Clara, CA (US); Ekaterina A. Mikhaylichenko, San Jose, CA (US); Boguslaw A. Swedek, Morgan Hill, CA (US); Thomas H. Osterheld, Mountain View, CA (US); Dominic J. Benvegnu, La Honda, CA (US); Lakshmanan Karuppiah, San Jose, CA (US)

(21) Appl. No.: 18/352,446

(22) Filed: Jul. 14, 2023

Related U.S. Application Data
(60) Provisional application No. 63/389,221, filed on Jul. 14, 2022.

(51) Int. Cl. B24B 49/04; B24B 57/02; B24B 37/013; B24B 37/26

(52) U.S. Cl. CPC B24B 49/045; B24B 57/02; B24B 37/013; B24B 37/26

(57) ABSTRACT

A chemical mechanical polishing system includes a support configured to hold a substrate face-up, a polishing article having a polishing surface smaller than an exposed surface of the substrate, a port for dispensing a polishing liquid, one or more actuators to bring the polishing surface into contact with a first portion of the exposed surface of the substrate and to generate relative motion between the substrate and the polishing pad and optically transmissive polymer window, an in-situ optical monitoring system, and a controller configured to receive a signal from the optical in-situ monitoring system and to modifying a polishing parameter based on the signal. The optical monitoring system includes a light source and a detector, the in-situ optical monitoring system configured to direct a light beam from above the support to impinge a non-overlapping second portion of the exposed surface of the substrate.

### CROSS-REFERENCE TO RELATED APPLICATIONS

This application claims the benefit of priority to U.S. Application No. 63/389,221, filed on Jul. 14, 2022, the contents of which are hereby incorporated by reference.

### TECHNICAL FIELD

This disclosure relates to in-situ monitoring of chemical mechanical polishing, and in particular to layer thickness monitoring in face-up polishing.

### BACKGROUND

An integrated circuit is typically formed on a substrate by the sequential deposition of conductive, semiconductive, or insulative layers on a silicon wafer. One fabrication step involves depositing a filler layer over a non-planar surface and planarizing the filler layer. For certain applications, the filler layer is planarized until the top surface of a patterned layer is exposed. A conductive filler layer, for example, can be deposited on a patterned insulative layer to fill the trenches or holes in the insulative layer. After planarization, the portions of the metallic layer remaining between the raised pattern of the insulative layer form vias, plugs, and lines that provide conductive paths between thin film circuits on the substrate. For other applications, such as oxide polishing, the filler layer is planarized, e.g., by polishing for a predetermined time period, to leave a portion of the filler layer over the nonplanar surface. In addition, planarization of the substrate surface is usually required for photolithography.

Chemical mechanical polishing (CMP) is one accepted method of planarization. This planarization method typically requires that the substrate be mounted on a carrier or polishing head. The exposed surface of the substrate is typically placed in a “face-down” orientation against a rotating polishing pad. The carrier head provides a controllable load through one or more pressure actuators to push the substrate against the polishing pad. An abrasive polishing slurry is typically supplied to the surface of the polishing pad.

To compensate for radial variations in thickness, due either to variations in the incoming substrate or variations in the polishing rate caused by polishing apparatus, a sensor can scan across the substrate during polishing and radially disposed chambers in the carrier head can be driven to different pressures.

### SUMMARY

Disclosed herein is are systems and methods for monitoring a thickness value for an exposed layer of a substrate in “face-up” chemical mechanical polishing. The substrate is arranged on a vacuum support such that a surface of the substrate to be planarized is exposed to contact with a rotary polishing article. The polishing article is brought into contact with exposed surface and rotated, polishing a portion of the exposed surface.

The system includes an optical in-situ monitoring system configured to direct a light beam onto and receive reflected light from the exposed surface of the substrate. The optical system receives the reflected light and generates a signal indicative of a thickness of a layer of material on the exposed surface. The optical monitoring system is in communication with a controller of the system and transmits the signal to the controller. The controller receives the signal and modifies a polishing parameter based on the signal.

In general, in a first aspect, the disclosure features a chemical mechanical polishing system that includes a support configured to a receive and hold a substrate, a polishing article having a polishing surface smaller than an exposed surface of the substrate, a port for dispensing a polishing liquid to an interface between the polishing pad and the substrate, an in-situ optical monitoring system, one or more actuators including a controller configured to receive a signal from the optical in-situ monitoring system and to modifying a polishing parameter based on the signal. The in-situ optical monitoring system includes a light source, a detector, and an optically transmissive polymer window. The light source is configured to direct a light beam through the optically transmissive polymer window and the detector is configured to receive reflections of the light beam through the optically transmissive polymer window. The one or more actuators are configured to bring the polishing surface into contact with a first portion of the exposed surface of the substrate, to bring the optically transmissive polymer window into contact with a non-overlapping second portion of the exposed surface of the substrate, and to generate relative motion between the substrate and the polishing pad and optically transmissive polymer window.

In another aspect, a chemical mechanical polishing system includes a support configured to a receive and hold a substrate, a polishing article having a polishing surface smaller than an exposed surface of the substrate, a port for dispensing a polishing liquid to an interface between the polishing pad and the substrate, an in-situ optical monitoring system, one or more actuators including a controller configured to receive a signal from the optical in-situ monitoring system and to modifying a polishing parameter based on the signal. The in-situ optical monitoring system includes a light source, a detector, and an optically transmissive polymer window. The light source is configured to direct a light beam directly onto the substrate, through the optically transmissive polymer window, through a water column in contact with the substrate and the detector is configured to receive reflections of the light beam directly from the substrate, through the optically transmissive polymer window or through a water column in contact with the substrate. The one or more actuators are configured to bring the polishing surface into contact with a first portion of the exposed surface of the substrate, to bring the in-situ optical monitoring system above a non-overlapping second portion of the exposed surface of the substrate, and to generate relative motion between the substrate and the polishing pad and in-situ optical monitoring system.

Particular implementations of the subject matter described in this specification can be implemented so as to realize one or more of the following technical advantages. Wafer-to-wafer (WTW) and within-wafer (WIW) polishing uniformity can be improved. Both radial and angular non-uniformity can be reduced. Determining a polishing parameter of the polishing operation facilitates directing the polishing operation to achieve a desired polishing profile. This polishing profile can be fed into an algorithm to increase material removal accuracy.

The details of one or more embodiments are set forth in the accompanying drawings and the description below. Other features and advantages will be apparent from the description and drawings, and from the claims.

### DESCRIPTION OF DRAWINGS

FIG. 1 illustrates a schematic cross-sectional view of an example of a polishing apparatus.

FIG. 2 illustrates a perspective view of the polishing system with an in-situ optical monitoring system.

FIGS. 3A and 3B are illustrations showing the polishing region, and a path of a transmissive window, respectively.

FIG. 4 is a flow chart diagram detailing the steps of a method of polishing.

FIG. 5 illustrates a schematic cross-sectional showing another implementation of an in-situ optical monitoring system.

FIG. 6 illustrates a schematic cross-sectional showing yet another implementation of an in-situ optical monitoring system.

FIG. 7A illustrates a schematic top view of a circular polishing pad on a substrate.

FIG. 7B illustrates a schematic cross-section of the polishing system of FIG. 7A.

FIG. 8A illustrates a schematic top view of an arc-shaped polishing pad on a substrate.

FIG. 8B illustrates a schematic cross-section of the polishing system of FIG. 8A.

In the figures, like references indicate like elements.

### DETAILED DESCRIPTION

In addition to radial variations in thickness, in some semiconductor chip fabrication processes there are angular variations in thickness, e.g., depending on the azimuthal angle around the center of the substrate. Like radial variations, the angular variations can be due to variations in the incoming substrate or caused by variations in the polishing rate induced by polishing apparatus. Various “touch-up” polishing processes have been proposed, e.g., using a small rotating disk-shaped polishing pad. However, such “touch-up” polishing processes contact the substrate in a small region and thus have low throughput. “Touch-up” polishing can also be referred to as location specific polishing (LSP).

Described herein is a location-specific polishing method which uses data collected in real-time from the exposed surface of the substrate as measured by an in-situ optical monitoring system. The system controller receives data indicative of the thickness of a layer of the exposed surface and modifies one or more polishing parameters to achieve a target thickness profile.

The parameters of the polishing roller, e.g., roller diameter, pad grit, etc., can be selected based on the substrate shape and/or thickness profile, thus providing flexibility for different polishing processes. Additionally, the polishing roller can be purchased conventionally or 3D printed, thereby realizing cost savings and reducing device down-time for maintenance. The controller functions to optimize substrate rotational speeds, polishing roller rotational speeds and pressures, roller orientation, and roller scanning profile to accomplish precise, location-specific material removal.

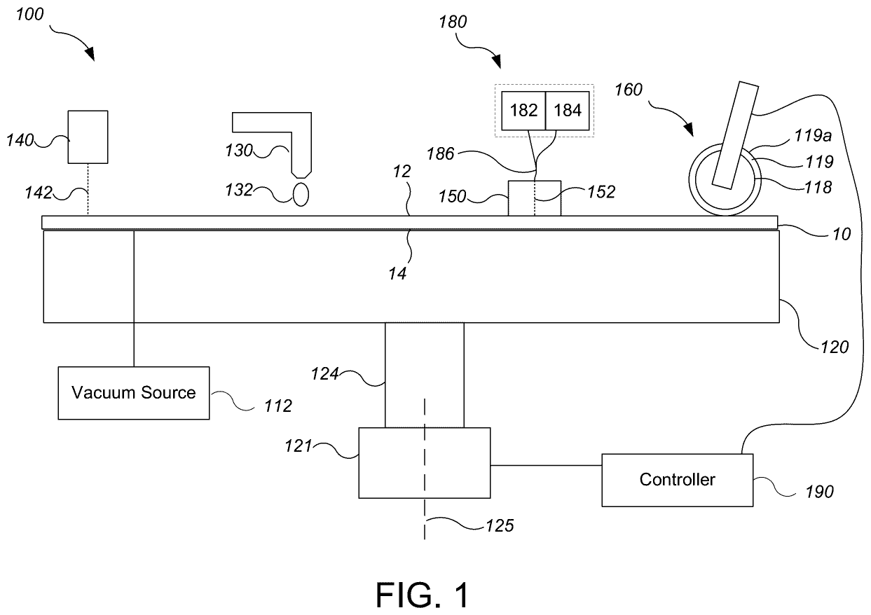

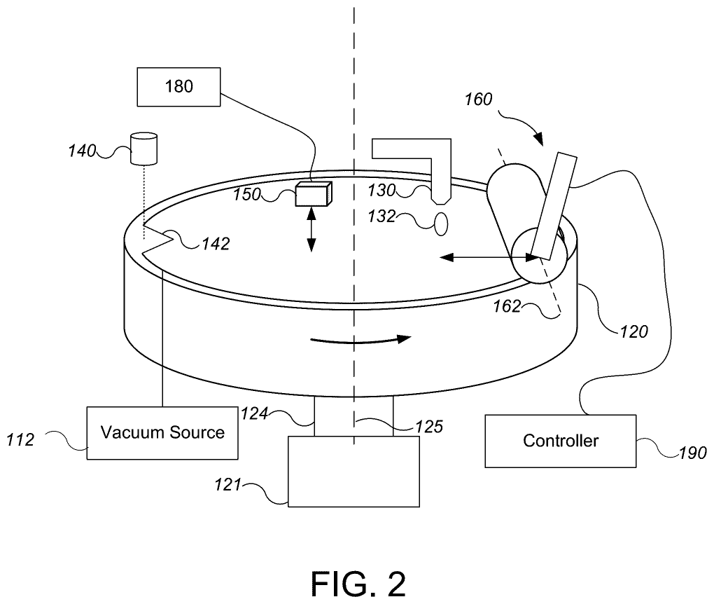

Referring to FIGS. 1 and 2, FIG. 1 illustrates an example of a polishing system 100 and FIG. 2 illustrates a perspective view of the exemplary polishing system 100. The polishing system 100 includes a rotatable disk-shaped chuck 120 on which a substrate 10 is situated. As an installed system, the chuck 120 holds the substrate in a “face-up” orientation, i.e., the planar top surface 12 that will be polished is substantially perpendicular to gravity and oriented such that the top surface 12 will support a polishing liquid that is dispensed on to the top surface 12 (although the polishing liquid can be spun off by rotation of the substrate 10).

The chuck 120 is operable to rotate about an axis of rotation 125. For example, an actuator, e.g., motor 121, e.g., a DC induction motor, can turn a drive shaft 124 to rotate the chuck 120. In operation, the substrate 10 is held to the top surface of the chuck 120, e.g., by a vacuum applied to the bottom surface 14 of the substrate 10 by a vacuum source 112, e.g., a vacuum chuck. The vacuum chuck 120 maintains the substrate 10 orientation and position on the chuck 120 while rotating about the axis of rotation 125. The vacuum chuck 120 exposes the entire surface, e.g., the top surface, of the substrate 10 to the polishing system 100 and does not impede the polishing process.

The polishing system 100 includes a first actuator operable to rotate a rotary drum 118 about a primary axis of rotation 162 (see FIG. 2; the axis extends out of the page in FIG. 1). A polishing layer 119 is affixed to at least a portion of the cylindrical outer surface of drum 118, thus forming a cylindrical polishing surface 119a. The drum 118 and affixed polishing layer 119 constitute a polishing roller 160. The drum 118 of FIG. 1 is cylindrical with a length longer than a diameter. The primary axis of rotation 162 is coaxial with the longitudinal axis of the roller 160. The roller 160 is arranged such that the primary axis is parallel with a front face, e.g., the exposed upper surface, of the substrate 10. In addition, the axis of rotation 162 can be perpendicular the radial segment extending from the axis of rotation 125 of the chuck to the longitudinal midpoint of the portion of the roller 160 that contacts the polishing surface 119a.

The polishing surface 119a of the roller 160 is composed of a material suitable for polishing and planarization of the substrate 10. The polishing layer 119 can include one or more layers. An outermost layer of the polishing layer 119 is a polishing layer. The material of the polishing layer can be a polymer, e.g., polyurethane, and can be microporous layer, for example, an IC1000 polishing layer material.

The polishing system 100 can include a port 130 to dispense polishing liquid 132, such as abrasive slurry, onto the polishing substrate 10 where it would be carried by rotation of the chuck 120 and substrate 10 to below the roller 160. Alternatively, the port could dispense the polishing liquid directly onto the roller 160.

The polishing system 100 includes a second actuator to control the vertical position of the roller 160 with respect to the substrate 10 and chuck 120. The second actuator operates to bring the roller 160 polishing surface into, and remove the roller 160 polishing surface from, contact with the substrate 10 surface. In a polishing operation, the roller 160 is brought into contact with the front face of the substrate 10 creating a contact area between the roller 160 polishing surface and the substrate 10 front face. The polishing system 100 commands the second actuator to apply a force to the roller 160, e.g., pressed, in a direction orthogonal to the exposed surface, e.g., toward the substrate 10. The force applied to the contact area via roller 160 can be in a range from 0.5 to 5 psi.

The rotational motion of the roller 160 polishing surface in the presence of the polishing liquid 132 causes a portion of the substrate 10 material in the contact area to be removed, e.g., polished, while not removing substrate 10 material outside of the contact area. If necessary, the roller 160 can be moved along an axis parallel to the plane of the substrate 10, e.g., right to left in FIG. 1, to reposition the contact area along the substrate 10 front face. The substrate 10 rotation and roller 160 rotational and translational motion create a relative motion between the roller 160 and the substrate 10 front face. While in contact with the substrate 10 the roller 160 rotational speed can be in a range from 10 rpm to 2500 rpm (e.g., 50 rpm to 1500 rpm).

The time period in which the roller 160 is in contact with the substrate 10 is a contact time. The dwell time of the roller over any particular region, in conjunction with the pressure and rotation rates, determine the amount of material removed from the substrate. After the contact time between the roller 160 and the substrate 10, the roller 160 can be removed from contact with the substrate 10 to stop polishing.

An azimuthal polishing profile can be controlled by synchronizing the roller pressure or position with the chuck rotation (at low chuck speeds), e.g., to correct for asymmetry.

A controller 190, such as a programmable computer, is connected to the motor 121 to control the rotation rate of the chuck 120. For example, the motor 121 can include an encoder that measures the rotation rate of the associated drive shaft. A feedback control circuit, which could be in the motor 121 itself, part of the controller 190, or a separate circuit, receives the measured rotation rate from the encoder and adjusts the current supplied to the motor 121 to ensure that the rotation rate of the drive shaft matches at a rotation rate received from the controller 190.

The system 100 includes a position sensor 140 to sense the angular position of the chuck 120 or the substrate 10. This permits orientation of the substrate 10 with respect to the chuck 120, orientation with respect to a polishing profile stored in the controller 190, or both.

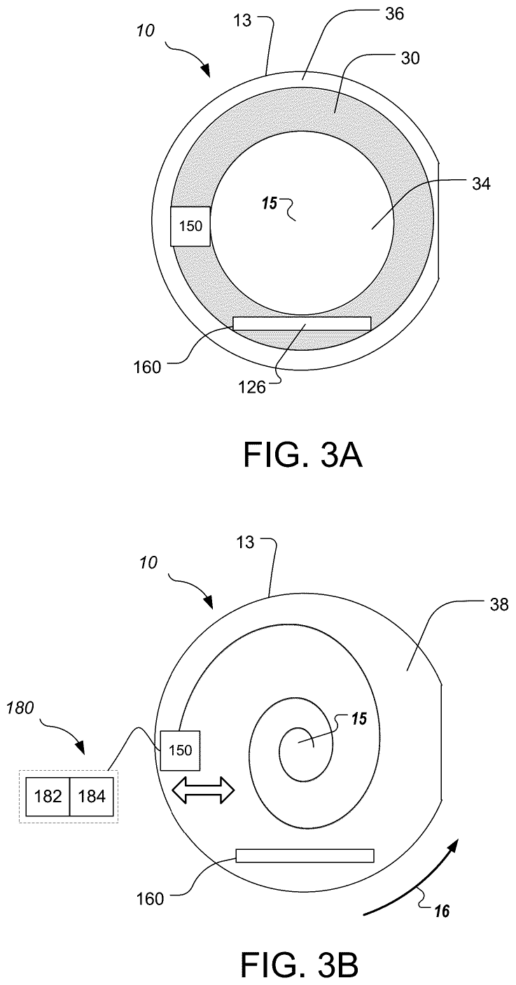

For example, the position sensor can be an optical sensor positioned near a rim of the chuck 120 and such that the sensor will overlie an annular edge of the substrate. The substrate can include a notch 142 (see FIG. 2) or a flat (see FIGS. 3A and 3B). Thus, due to the rotation of the substrate 10 with the chuck 120, the position sensor 140 intermittently passes over the notch 142 or flat, resulting in a change in reflectivity, which is optically detected by the sensor 140. As another example, the optical sensor 140 can be an optical interrupter. In particular, the sensor 140 can include a light source and a detector, and a tab can extend from the edge of the chuck. Due to rotation of the chuck, the tab will intermittently pass between the light source and detector, interrupting the light beam, which is optically detected by the sensor. The frequency of detection of the notch or of the optical interruption provides a rotation rate of the chuck and substrate 10.

The polishing system 100 includes an in-situ optical monitoring system 180 for measuring signals indicative of a thickness of an exposed layer of the surface of the substrate 10. The optical monitoring system 180 includes a light source 182 and a sensor 184 connected to an optically transmissive window 150. In operation, the window 150 is brought into physical contact with the top surface 12 of the substrate 10.

The light source 182 generates light which is transmitted to the window 150 by the connection, such as, by an optical fiber 186, e.g., a fiber optic cable. In some implementations, the light source 182 is a laser, flash lamp, or discharge lamp. In one example, the light is a broad spectrum across the visible wavelengths, e.g., white light. In alternative examples, the light has a bandwidth including a portion of the visible wavelengths, such as a 10 nm bandwidth, or a 100 nm bandwidth. The light source 182 can include any necessary filter, mirror, or diffraction grating to generate light of a selected spectrum or bandwidth.

The window 150 is composed of a transmissive material, e.g., at least 90%, at least 95%, or at least 99% transmissive to wavelengths being monitored by the detector, that is chemically compatible with the polishing process. The window 150 is of sufficient durability to withstand the frictional forces generated by contact between the window 150, substrate 10, and polishing liquid 132. The window 150 can be solid, e.g., substantially non-porous, polymer body.

Suitable polymers include polyurethane, polycarbonate, polymethyl methacrylate (PMMA), acrylic, polyethylene perephthalate (PET), or amorphous copolyester (PETG). In some implementations, the window 150 is formed of the same polymer composition as the polishing layer of the polishing layer 119 on the drum 118. In some implementations, the polishing layer of the polishing layer 119 is a polymer matrix with pores, e.g., liquid-filled pores or hollow microspheres, whereas the window 150 is formed of the same polymer matrix but without the pores. In some implementations, window 150 and the matrix material of the polishing layer 119 use the same two (or more) monomer or polymer components, but in different weight percentage contributions so as to provide different compressibility.

The window 150 contacts the top surface of the substrate 10. The light forms a light beam 152 that is transmitted through the window 150, reflects off the top surface of the substrate 10, and is reflected back through the window 150. The reflected light is received, e.g., by the optical fiber 186, and transmitted to an optical sensor 184 of the optical monitoring system 180. For this configuration, the light beam 152 impinges the substrate 10 normal to the exposed surface 12. The optical sensor 184 can be a spectrometer.

The sensor 184 receives reflected light from the window 150, and the optical monitoring system 180 determines a thickness profile indicative of the thickness of the layer of the substrate beneath the window 150 based on the signal from the sensor 184. The controller 190 can store a target thickness profile for the layer of the substrate 10 being polished.

Referring again to FIGS. 1 and 2, during the polishing operation, the contact time, roller 160 rotational- and translational speed, and pressure parameters can be determined based upon the amount of material removed to achieve the target thickness profile and compose a correction profile. The correction profile can be loaded into a controller of the polishing system 100 to control the chuck 110, roller 160, and liquid 132 flow rate. For example, the controller 190 controls a polishing parameter of the polishing operation to achieve the target thickness profile. Some examples of the polishing parameters include a rotational speed (e.g., of the chuck 120, or of the roller 160), a pressure (e.g., of the roller 160), a contact time, a translational speed, an orientation angle, or a polishing region (e.g., annular region 30). Specific examples of the polishing parameter includes one or more of a pressure of the polishing pad against the substrate, a lateral position of the polishing surface relative to the substrate, a rate of motion of the polishing surface relative to the substrate, a polishing endpoint, a rotation rate of the roller, or an angle of the primary axis relative to a radius of the substrate.

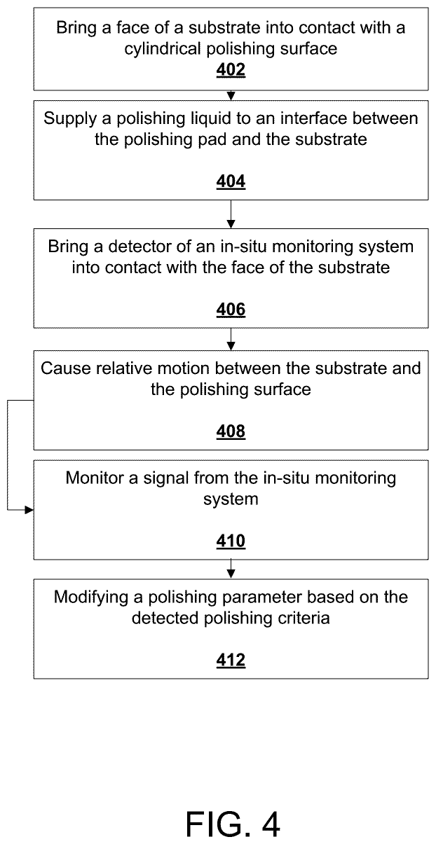

Referring to FIG. 3A, the roller 160 primary axis can be oriented at any angle in a range from 0° (e.g., parallel with) to 90° (e.g., perpendicular to) with respect to a ray (e.g., segment) connecting the centerpoint 15 of the substrate 10 to the centerpoint 126 of the roller 160. For example, the roller 160 primary axis of FIG. 4A is oriented perpendicular to (e.g., at 90° from) a ray connecting the centerpoint 15 of the substrate 10 to the centerpoint 134 of the roller 160.

The edges of the roller 160 are positioned at or near the edge 13 of the substrate 10, or radially inward from the edge 13, e.g., by 1-30 mm. In some implementations, the roller 160 is substantially perpendicular to (e.g., 80-90° from) the ray connecting the substrate centerpoint 15 to the roller centerpoint 126. The roller 160 contacts the substrate 10 over a portion of the surface, and in this configuration, the polishing action is concentrated at an annular region 30 of the top surface of the substrate 10 that is spaced apart from the substrate edge 13. Said another way, the portion of the substrate which contacts the roller 160 and rotated around the centerpoint forms the annular region 30. A central region 34 radially inward of the annular region 30 and a second annular region 36 surrounding the polished annular region 30 are not polished.

FIG. 3B shows a top-view of the substrate 10 during a polishing operation in which the window 150 is moved in a direction shown by the double-sided arrow adjacent the window 150 in FIG. 3B. In some implementations, the direction is in a radial direction, such as between a point on the edge 13 and the centerpoint 15. As the substrate 10 is rotated with the chuck 120 in the direction of motion 16, the window 150 follows a spiral path 38 toward the centerpoint 15. The dimensions of the window 150 determine a portion of the substrate 10 which the window 150 covers while following the path 38. The portion which the window 150 contacts, and the portion that the roller 160 contacts, are non-overlapping.

Referring now to FIG. 4, a flow chart diagram outlining the steps of a method 400 of polishing a substrate is shown. The method 400 includes the following steps.

The method includes bringing a face of the substrate 10 into contact with the roller 160 (step 402). The polishing surface of the roller 160 rotates around the primary axis of rotation parallel to the surface being polished.

The method includes supplying a polishing liquid 132 to an interface between the roller 160 and the substrate 10 (step 404). The polishing liquid 132 can include abrasive particles suspended in a carrier fluid, e.g., an abrasive slurry. The port 130 of the system 100 dispenses the liquid 132 onto the polishing surface of the substrate 10.

The method includes bringing a window 150 of an in-situ optical monitoring system 180 into contact with the face of the substrate (step 406). In some implementations, the detector 184 of the optical monitoring system 180 is optically coupled to the transparent optical window 150 through an optically transmissive connection, such as a fiber optic cable.

The method includes causing relative motion between the substrate 10 and the roller 160 (step 408). Relative motion can also be generated between the substrate 10 and the window 150. An example of the relative motion include rotating the polishing surface of the roller 160 about the primary axis while pressing the polishing surface against the exposed front face of the substrate 10. Additionally or alternatively, rotating the chuck 120 supporting the substrate 10 causes relative motion between the substrate 10 and both the roller 160 and the window 150. Relative motion can between the substrate 10 and the window 150 can also be generated by sweeping the window laterally, e.g., radially, across the substrate 10. This lateral motion can be in conjunction with rotation of the chuck 120 to generate a spiral sweep of the window 150 across the substrate 10.

The method includes monitoring a signal from the in-situ optical monitoring system 180 (step 410). The light source 182 generates light which is transmitted to the window 150. The light reflects off of the exposed surface of the substrate 10 contacting the window 150. The reflected light is captured by the detector 184, or alternatively by the fiber optic connection connecting the window 150 to the detector 184. The optical monitoring system 180 generates a thickness signal based on the reflected light. Alternatively, the optical monitoring system 180 communicates a measurement of the reflected light to the system controller 105, which generates the thickness signal. Because the window 150 sweeps laterally across the substrate 10, the system can generate a thickness profile, e.g., a radial thickness profile.

The method includes modifying a polishing parameter based on the measured thickness profile meeting desired polishing criteria (step 412). The system controller 105 receives the measured thickness profile compares the measured thickness profile to a target profile. If a difference between the measured thickness profile and the target profile exceeds a threshold value, the system controller 105 may alter one or more polishing parameters, e.g., the position or rotational speed of the roller, in order to compensate. Alternatively or in addition, the system controller 105 can halt polishing once the measured thickness profile matches a target thickness profile.

Although the description above has focused on a window that contacts the substrate, several other techniques could be used.

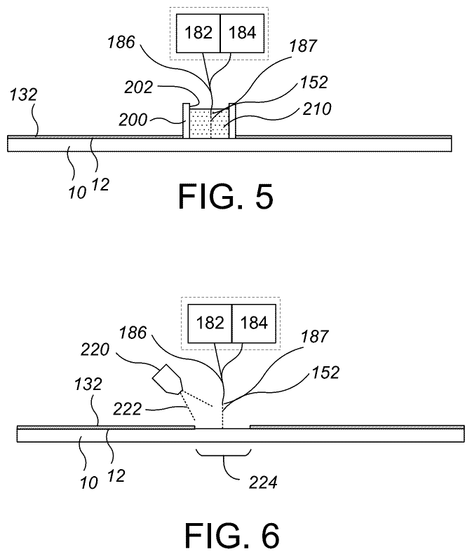

For example, the light beam could be transmitted through a “water column” to the substrate surface. Referring to FIG. 5, a barrier 200 having an aperture 202 therethrough can be placed in contact with the exposed surface 12 of the substrate 10. A transparent liquid 210, e.g., water, is placed in the aperture 202 to form a “water column” of transparent liquid in contact with the exposed surface 12 of the substrate 10. The barrier 200 can both hold the transparent liquid 210 to provide the water column, and block slurry 132 from mixing with the transparent liquid 210 in order to reduce noise. An end 187 of the optical fiber 186 is placed into the transparent liquid 210 so that the light beam 152 passes through the transparent liquid 210 of the “water column” to impinge and be reflected back from the substrate. In this case, step 406 shown in FIG. 4 would include bringing the water-column into contact with the face of the substrate.

As another example, slurry could be blown off the exposed surface of the substrate with a jet of gas. Referring to FIG. 6, a nozzle 220 is positioned above the substrate. A gas, e.g., pure air or nitrogen gas, is directed through the nozzle 220 to form a jet 222 of gas. The nozzle 220 is positioned such that the jet 222 of gas blows any polishing liquid 132 off of the substrate in a region 224 where the light beam 152 impinges the exposed surface of the substrate 10. This prevents the polishing liquid, e.g., abrasive particles in the polishing liquid, from scattering a portion of the light beam and creating noise in the measured signal. a detector of an in-situ monitoring system into contact with the face of the substrate. In this case, step 406 shown in FIG. 4 would be replaced with a step of blowing polishing liquid off the face of the substrate.

In addition, although the description above has focused on a roller with a cylindrical polishing layer, the optical monitoring techniques discussed above, e.g., for FIGS. 1, 5 and 6, can be used with other polishing layer configurations.

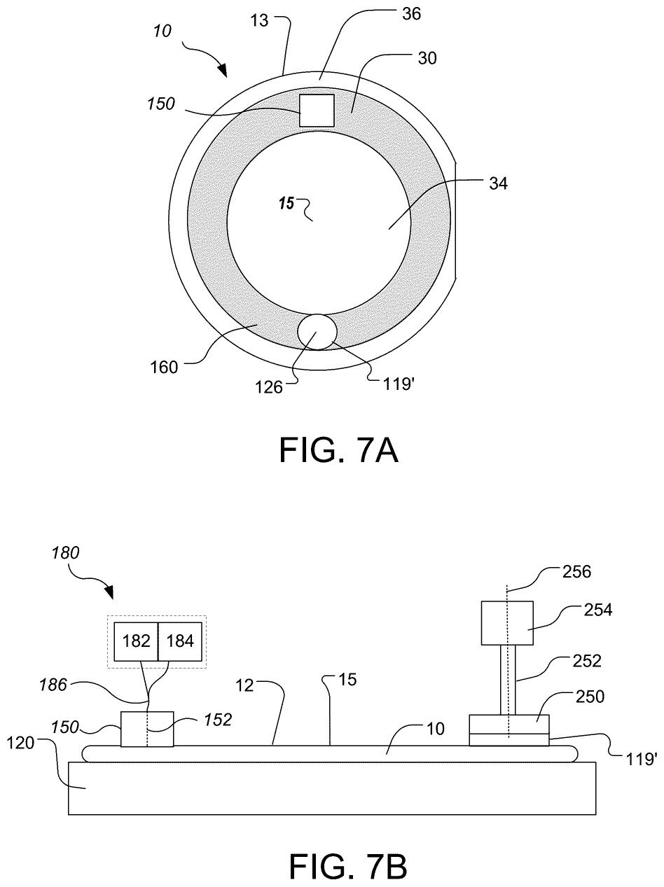

For example, the polishing system can use a rotatable circular disk-shaped polishing pad that is smaller than the substrate. Referring to FIGS. 7A and 7B, a circular polishing layer 119′, i.e., a polishing pad, can be held on the bottom of a pad carrier 250, e.g., a metal disk. The pad 119′ contacts just a portion of the substrate 10. In some implementations, the pad carrier 250 is be rotated by a drive shaft 252 driven by a motor 254. The motor 254 can rotate the polishing pad 119′ about an axis 256 that passes through the center of the polishing pad 119′. In some implementations, the axis 256 is slightly offset from the center of the polishing pad 119′, such that the pad performs an orbital motion on the substrate. In either case, due to the rotation of the chuck 120, in the configuration shown in FIG. 7A the polishing action is concentrated at an annular region 30 of the top surface of the substrate 10 that is spaced apart from the substrate edge 13.

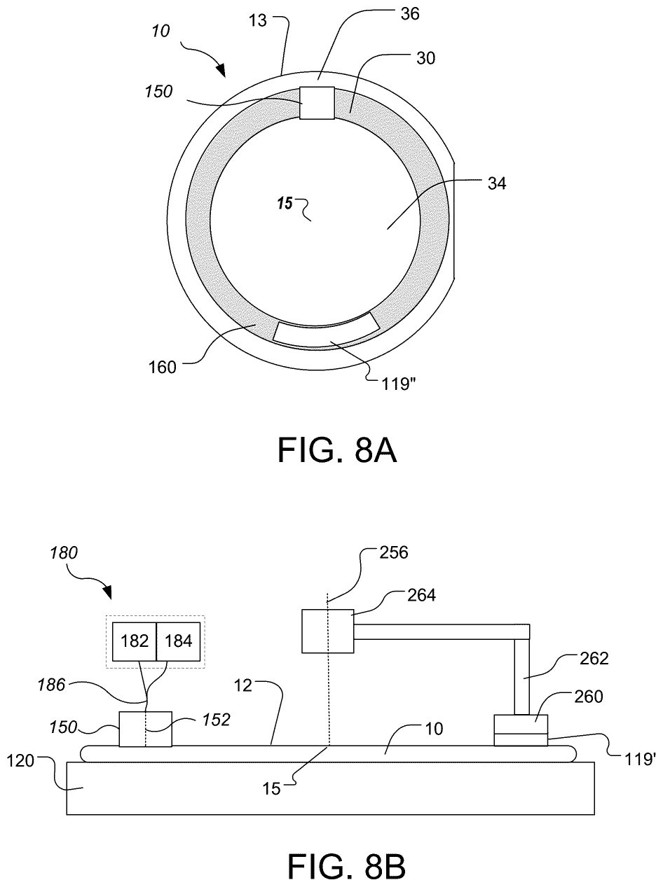

As another, the polishing system can use an arc-shaped polishing pad that is smaller than the substrate. Referring to FIGS. 8A and 8B, the arc-shaped polishing pad 119″ can be held on the bottom of a pad carrier 260, e.g., an arc-shaped metal piece. If the pad carrier 260 is held stationary while the chuck 120 rotates, the polishing action is concentrated at an annular region 30 of the top surface of the substrate 10 that is spaced apart from the substrate edge 13. Alternatively, the pad carrier 250 can be affixed at the end of an arm 262 that is rotated by a motor 264 such that the pad carrier 250 and arc-shaped polishing pad 119″ orbit about an axis 268 that passes through the centerpoint 15 of the substrate 10.

While this specification contains many details, these should not be construed as limitations on the scope of what may be claimed, but rather as descriptions of features specific to particular examples. Certain features that are described in this specification in the context of separate implementations can also be combined. Conversely, various features that are described in the context of a single implementation can also be implemented in multiple embodiments separately or in any suitable subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products

A number of implementations have been described. Nevertheless, it will be understood that various modifications may be made without departing from the spirit and scope of the invention. Accordingly, other implementations are within the scope of the following claims.

What is claimed is:

1. A chemical mechanical polishing system, comprising:
a support configured to a receive and hold a substrate in a plane;
a rotary drum having a cylindrical surface to hold a cylindrical polishing pad, the rotary drum having a primary axis of rotation parallel to a longitudinal axis of the rotary drum and parallel to the plane;
a first actuator to rotate the drum about the first axis;
a second actuator to bring the polishing pad on the rotary drum into contact with the substrate;
a port for dispensing a polishing liquid to an interface between the polishing pad and the substrate;
an in-situ monitoring system electrically coupled to a detector and configured to receive a signal from the detector; and
a controller, comprising at least one processor, and a data store coupled to the at least one processor having instructions stored thereon which, when executed by the at least one processor, causes the at least one processor to perform operations comprising
bringing a surface of a substrate into contact with a cylindrical polishing surface having a primary axis of rotation parallel to the polishing surface,
supplying a polishing liquid to an interface between the polishing pad and the substrate,
bringing a detector of an in-situ monitoring system into contact with the surface of the substrate,
causing relative motion between the substrate and the polishing surface, the relative motion including at least rotating the polishing surface about the primary axis while pressing the polishing surface against a front face of the substrate,
monitoring a signal from the in-situ monitoring system; and
modifying a polishing parameter based on the signal.

2. The system of claim 1, wherein the support is rotatable about a second axis.

3. The system of claim 2, wherein the first axis is substantially perpendicular to a segment extending from the second axis to a centerpoint of the rotary drum.

4. The system of claim 1, wherein the relative motion further comprises moving the polishing surface parallel to the plane of the polishing surface.

5. The system of claim 1, wherein the drum has a length greater than its diameter.

6. The system of claim 1, further comprising a detector for receiving a reflected signal from an edge portion of the substrate.

7. The system of claim 6, the operations further comprising determining an angular orientation of the substrate based on the received reflected signal.

8. The system of claim 6, the operations further comprising modifying a polishing parameter based on the received reflected signal.

9. The system of claim 1, wherein the controller is configured to determine a thickness of a top-most layer of the face of the substrate, or a thickness profile of the top-most layer of the face of the substrate.

10. The system of claim 1, wherein the polishing parameter is a polishing surface pressure, lateral position, or polishing endpoint.

11. A method of polishing, comprising:
bringing a face of a substrate into contact with a cylindrical polishing surface having a primary axis of rotation parallel to a longitudinal axis of the cylindrical polishing surface;
supplying a polishing liquid to an interface between the polishing pad and the substrate;
bringing an optically transmissive polymer window of an in-situ optical monitoring system into contact with the face of the substrate;
causing relative motion between the substrate and the polishing surface, the relative motion including at least rotating the polishing surface about the primary axis while pressing the polishing surface against a front face of the substrate;
monitoring a signal from the in-situ monitoring system; and
modifying a polishing parameter based on the signal.

12. The method of claim 11, wherein cylindrical polishing surface extends across an edge of the substrate.

13. The method of claim 11, wherein ends of the cylindrical polishing surface are spaced radially inward of an edge of the substrate.

14. The method of claim 13, wherein opposing ends of the cylindrical polishing surface are positioned within 40 mm of the edge of the substrate.

15. The method of claim 11, wherein the relative motion further comprises moving the polishing surface parallel to a plane of the polishing surface.

16. The method of claim 11, comprising rotating the substrate about a second axis.

17. The method of claim 11, wherein the primary axis is substantially perpendicular to a segment extending from a second axis to a centerpoint of the cylindrical polishing surface.

18. The method of claim 11, wherein the detected polishing criteria comprises a thickness of a top-most layer of the substrate, or a thickness profile of the top-most layer of the substrate.

19. The method of claim 11, wherein the polishing parameter is a polishing surface pressure, lateral position, or polishing endpoint.

20. The system of claim 11, wherein the polishing parameter includes a rotation rate of the roller or an angle of the axis relative to a radius of the substrate.
